(19) United States
(12) Patent Application Publication
(10) Pub. No.: US 2026/0231477 A1
(43) Pub. Date: Aug. 6, 2026

(54) ELECTRONIC DEVICE

(71) Applicant: InnoLux Corporation, Miao-Li County (TW)

(72) Inventors: Cheng-Min WU, Miao-Li County (TW); Ming-Jhih CHEN, Miao-Li County (TW); Cing-Hong CHEN, Miao-Li County (TW)

(21) Appl. No.: 19/439,791

(22) Filed: Jan. 5, 2026

(30) Foreign Application Priority Data
Feb. 5, 2025 (CN) 202510127801.2

(51) Int. Cl. H10D 30/67; H10H 29/32

(52) U.S. Cl. CPC H10D 30/6757; H10H 29/32

(57) ABSTRACT

An electronic device includes a substrate, a first metal layer, a semiconductor layer and a second metal layer. The first metal layer is disposed on the substrate. The semiconductor layer is disposed on the substrate, and includes a first channel area, a connection area and a second channel area, wherein the first channel area and the second channel area overlap with the first metal layer, and the connection area connects the first channel area and the second channel area. The second metal layer is disposed on the semiconductor layer, and includes a first pattern and a second pattern, wherein the first pattern is electrically connected to the first channel area, and the second pattern is electrically connected to the second channel area. The first channel area has a first width, the second channel area has a second width, and the first width is different from the second width.

### CROSS-REFERENCE TO RELATED APPLICATIONS

This application claims the benefits of the Chinese Patent Application Serial Number 202510127801.2, filed on Feb. 5, 2025, the subject matter of which is incorporated herein by reference.

### BACKGROUND

### Field of the Disclosure

The present disclosure relates to an electronic device and, more specifically, to an electronic device that uses different channel widths in its components.

### Description of Related Art

In electronic devices, such as display devices or touch screen displays, components (for example, transistors in pixel circuits) have a current input (Ion) to charge the pixel electrode when the channel is turned on, and when the channel is turned off, the charge voltage of the pixel electrode is maintained. Ideally, the leakage current (Ioff) is expected to be zero at this moment, but in reality, some leakage current still exists. As the channel width becomes narrower, the resistance increases, resulting in a decrease in the current input and leakage current. This results in an inability to provide the required charging capacity due to the low current input. Conversely, as the channel width becomes wider, the resistance decreases, resulting in an increase in the current input and leakage current, which leads to a problem of display flicker due to the excessive leakage current.

Therefore, it is desired to provide an improved electronic device to alleviate and/or obviate the aforementioned problems.

### SUMMARY

The present disclosure provides an electronic device, which includes: a substrate; a first metal layer disposed on the substrate; a semiconductor layer disposed on the substrate and including a first channel area, a connection area, and a second channel area, wherein the first channel area and the second channel area overlap with the first metal layer, and the connection area connects the first channel area and the second channel area; and a second metal layer disposed on the semiconductor layer and including a first pattern and a second pattern, wherein the first pattern is electrically connected to the first channel area, and the second pattern is electrically connected to the second channel area, wherein the first channel area has a first width, the second channel area has a second width, and the first width is different from the second width.

Other novel features of the disclosure will become more apparent from the following detailed description when taken in conjunction with the accompanying drawings.

### BRIEF DESCRIPTION OF DRAWINGS

FIG. 1A is a schematic diagram illustrating the structural layout of an electronic device according to an embodiment of the present disclosure;

FIG. 1B is a schematic diagram illustrating the simplified structural layout of an electronic device according to an embodiment of the present disclosure;

FIG. 2 is a schematic diagram illustrating the structural layout of an electronic device according to another embodiment of the present disclosure;

FIG. 3A is a schematic diagram illustrating the structural layout of an electronic device according to another embodiment of the present disclosure; and

FIG. 3B is a schematic diagram illustrating the simplified structural layout of an electronic device according to another embodiment of the present disclosure.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to “comprise”, “have”, “include” an element, it means that the component may include one or more of the elements, and the component may include other elements at the same time, and it does not mean that the component has only one of the element, except otherwise specified.

Moreover, in the present specification, the ordinal numbers, such as “first” or “second”, are only used to distinguish a plurality of elements having the same name, and it does not means that there is essentially a level, a rank, an executing order, or an manufacturing order among the elements, except otherwise specified. The ordinal numbers of the elements in the specification may not be the same in claims. For example, a “second” element in the specification may be a “first” element in the claims.

In the present specification, except otherwise specified, the feature A “or” or “and/or” the feature B means only the existence of the feature A, only the existence of the feature B, or the existence of both the features A and B. The feature A “and” the feature B means the existence of both the features A and B.

Moreover, in the present specification, the terms, such as “top”, “upper”, “bottom”, “front”, “back”, or “middle”, as well as the terms, such as “on”, “above”, “over”, “under”, “below”, or “between”, are used to describe the relative positions among a plurality of elements, and the described relative positions may be interpreted to include their translation, rotation, or reflection.

Furthermore, the terms recited in the specification and the claims such as “above”, “over”, “on”, “below”, or “under” are intended that an element may not only directly contacts other element, but also indirectly contact the other element.

Furthermore, the term recited in the specification and the claims such as “connect” is intended that an element may not only directly connect to other element, but also indirectly connect to other element. On the other hand, the terms recited in the specification and the claims such as “electrically connect” and “couple” are intended that an element may not only directly electrically connect to other element, but also indirectly electrically connect to other element.

In addition, in the specification and claims, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those skilled in the art, the background of the present disclosure or the context of the present specification, and should not be read by an ideal or over-formal way.

In addition, the electronic devices of the present disclosure may include display devices, sensing devices, automotive devices, tiled devices and touch devices, but not limited thereto. The display device may be any type of display device, such as a color display device, a transparent display device, a double-sided display device, a virtual reality display device, an augmented reality display device, a 3D display device, a tiled display device, a flexible display device, a foldable display device, a stretchable display device, and a rollable display device, but not limited thereto. The display device may, for example, include a liquid crystal, a light emitting diode, fluorescence, phosphor, other suitable display media, or a combination thereof, but not limited thereto. The display device may be a non-self-luminous display device or a self-luminous display device. The electronic device may include electronic components, wherein the electronic components may include passive components and active components, such as capacitors, resistors, inductors, diodes, transistors, etc. The diode may include a light emitting diode (LED) or a photodiode. The light emitting diode may include, for example, an organic light emitting diode (OLED), a sub-millimeter light emitting diode (mini LED), a micro light emitting diode (micro LED) or a quantum dot light emitting diode (quantum dot LED), but not limited thereto. The tiled device may be, for example, a display tiled device or an antenna tiled device, but not limited thereto. It should be noted that the electronic device may be any combination of the foregoing, but not limited thereto. In addition, the electronic device may be a bendable or flexible electronic device. It should be noted that the electronic device may be any combination of the foregoing, but not limited thereto. In addition, the appearance of the electronic device may be rectangular, circular, polygonal, a shape with curved edges or other suitable shapes. The electronic device may have a peripheral system such as a drive system, a control system, a light source system, a shelf system, etc. to support the display device or the tiled device. For the convenience of explanation, the following description will be based on the state of the electronic device as a display device, but the present disclose is not limited thereto.

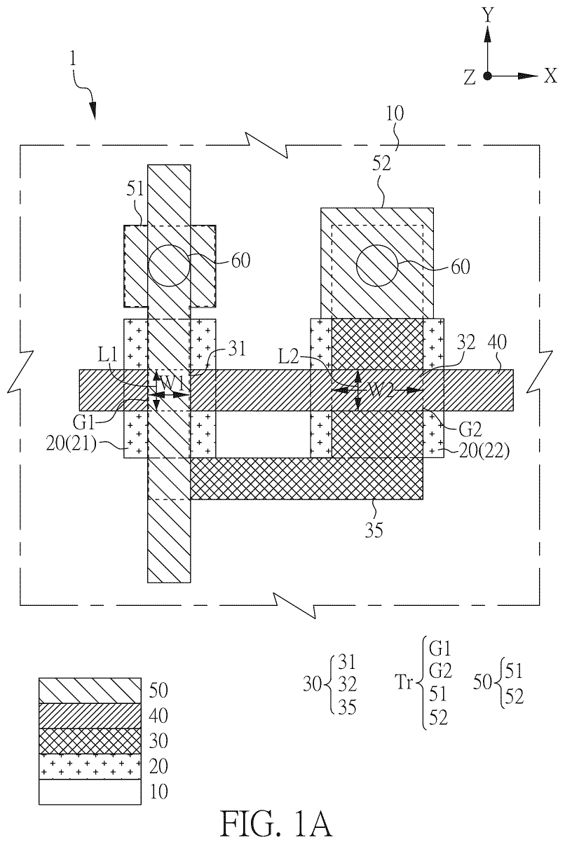

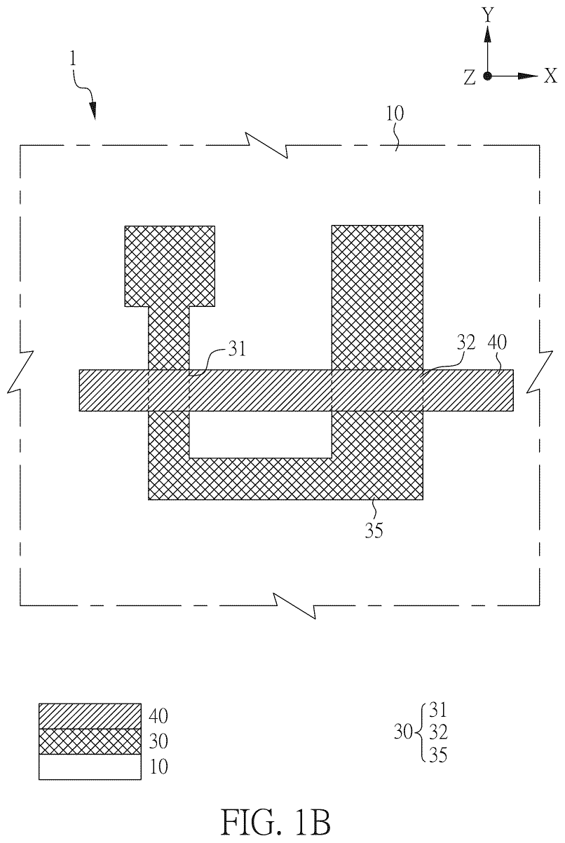

Please refer to FIG. 1A, which is a schematic diagram illustrating the structural layout of an electronic device according to an embodiment of the present disclosure, and FIG. 1B, which is a schematic diagram illustrating the simplified structural layout of an electronic device according to an embodiment of the present disclosure. For clarity of explanation, FIG. 1A mainly shows a top view of an component of the electronic device 1 in the Z direction and omits the illustration of other structures, wherein the component may be, for example, a transistor with a dual gate structure. Due to the dual gate structure, the transistor may have two channels. As shown in FIG. 1A, the electronic device 1 includes a substrate 10, a metal shielding layer 20, a semiconductor layer 30, a first metal layer 40 and a second metal layer 50. FIG. 1B only shows the substrate 10, the semiconductor layer 30 and the first metal layer 40 so as to clearly show the structural layout of the electronic device, wherein the metal shielding layer 20 is arranged on the substrate 10, the first metal layer 40 is arranged on the substrate 10, the semiconductor layer 30 is arranged on the substrate 10, and the second metal layer 50 is arranged on the semiconductor layer 30. In one embodiment, the metal shielding layer 20, the semiconductor layer 30, the first metal layer 40 and the second metal layer 50 are arranged in sequence on the substrate 10, while this is only an example but not a limitation.

The semiconductor layer 30 includes a first channel area 31, a connection area 35, and a second channel area 32. The first channel area 31 and the second channel area 32 overlap with the first metal layer 40, and the connection area 35 connects the first channel area 31 and the second channel area 32. Specifically, as shown in FIG. 1A and FIG. 1B, in this embodiment, the semiconductor layer 30 is arranged substantially in a U-shape, and the first metal layer 40 is arranged substantially in a long rectangular shape. However, this is for example only but not limitation. Therefore, the first channel area 31 is defined as a portion of the semiconductor layer 30 that overlaps with the first metal layer 40, the second channel area 32 is defined as another portion of the semiconductor layer 30 that overlaps with the first metal layer 40, and the connection area 35 is a portion of the semiconductor layer 30 that connects the first channel area 31 and the second channel area 32. For example, the connection area 35 may be in a U-shape, but it is not limited thereto. The first channel area 31 has a first width W1, and the second channel area 32 has a second width W2. The first width W1 is different from the second width W2. That is, the first width W1 may be greater than the second width W2, or the second width W2 may be greater than the first width W1. In this embodiment, the second width W2 is greater than the first width W1. Furthermore, as shown in FIG. 1A and FIG. 1B, the first channel area 31 has a first length L1, and the second channel area 32 has a second length L2. The first length L1 is equal to the second length L2. Therefore, the ratio of the first width W1 to the first length L1 (W1/L1) of the first channel area 31 is different from the ratio of the second width W2 to the second length L2 (W2/L2) of the second channel area 32. However, the present disclosure is not limited thereto. In other embodiments, the first length L1 of the first channel area 31 and the second length L2 of the second channel area 32 may be different.

The second metal layer 50 disposed on the semiconductor layer 30 includes a first pattern 51 and a second pattern 52. Since the first pattern 51 and the second pattern 52 substantially overlap with the semiconductor layer 30 and are respectively located at the two ends of the U-shaped layout of the semiconductor layer 30, the first pattern 51 may be electrically connected to the first channel area 31, and the second pattern may be electrically connected to the second channel area 32.

The metal shielding layer 20 is disposed between the substrate 10 and the semiconductor layer 30. The metal shielding layer 20 at least overlaps with the first channel area 31 and the second channel area 32 to shield the first channel area 31, the second channel area 32, and adjacent areas thereof so as to prevent light interference. In this embodiment, as shown in FIG. 1A and FIG. 1B, the metal shielding layer 20 has two shielding patterns 21 and 22 that overlap with the first channel area 31 and the second channel area 32, respectively. However, the present disclosure is not limited thereto. In some embodiments, the shielding pattern of the metal shielding layer 20 may overlap with both the first channel area 31 and the second channel area 32.

With the aforementioned substrate 10, metal shielding layer 20, semiconductor layer 30, first metal layer 40 and second metal layer 50, the electronic device 1 may be at least provided with one transistor Tr with a dual-gate structure, wherein the first metal layer 40 includes a first gate area G1 and a second gate area G2 of the transistor Tr. The first gate area G1 is a portion of the first metal layer 40 that overlaps with the semiconductor layer 30, and the second gate area G2 is another portion of the first metal layer 40 that overlaps with the semiconductor layer 30. For example, the first gate area G1 overlaps with the first channel area 31, and the second gate area G2 overlaps with the second channel area 32. The first pattern 51 in the second metal layer 50 is the source of the transistor Tr, and the second pattern 52 in the second metal layer 50 is the drain of the transistor Tr. The source and the drain are each electrically connected to the semiconductor layer 30 through contact vias 60 in the insulating layer (not shown) between the second metal layer 50 and the semiconductor layer 30, wherein the source is connected to the data line, and the first gate area G1 and the second gate area G2 are connected to the scan line, while the present disclosure is not limited thereto.

In addition, it should be noted that the length L1 of the channel area 31 refers to the distance of the channel area 31 in the direction in which the semiconductor layer 30 extends between the source and drain, the length L2 of the channel area 32 refers to the distance of the channel area 32 in the direction in which the semiconductor layer 30 extends between the source and drain, the width W1 of the channel area 31 refers to the distance between two opposite sides of the channel area 31 in the direction in which the semiconductor layer 30 extends between the source and the drain, and the width W2 of the channel area 32 refers to the distance between two opposite sides of the channel area 32 in the direction in which the semiconductor layer 30 extends between the source and the drain. Therefore, based on different circuit layouts, such as but not limited to different relative positions between the source and the drain, different layout shapes of the semiconductor layer 30 or the first metal layer 40, the widths W1 and W2 of the two channel areas 31 and 32 may be measured in different directions. In this embodiment, the widths W1 and W2 of the channel areas 31 and 32 are both measured in the X direction, but it is not limited thereto.

In the aforementioned transistor Tr with a dual-gate structure, since the first width W1 of the first channel area 31 is different from the second width W2 of the second channel area 32, the transistor Tr of the present disclosure may exhibit unexpected performance in terms of current input (Ion) and leakage current (Ioff) compared to prior designs with a single channel width. For example, the current input (Ion) when the widths of two channel areas of the transistor Tr are respectively W1 and W2 will be between the current input (Ion) when the widths of both channel areas are W1 and the current input (Ion) when the widths of both channel areas are W2. In some embodiments, the current input value of the transistor Tr is equivalent to the magmitude of the current input of the transistor Tr when the widths of the channel areas 31 and 32 are each the average of the widths of the channel areas of the transistor Tr (that is, (W1+W2)/2), but it is not limited thereto. Taking another example, the leakage current value of the transistor Tr is approximate to the magnitude of leakage current when both channel areas of the transistor have a narrower channel width (for example, W1). Therefore, in the present disclosure, the first width W1 and the second width W2 are designed to be different from each other, thereby alleviating the problem of display flicker caused by leakage current with only a small sacrifice of charging capacity.

Furthermore, in practical applications, the channel width may be designed to be between 1.5 μm and 7.5 μm. Based on the fact that the current input value of the transistor Tr increases with the increase in the average width of the two channels, the overall current input value will be between the current input value when both channel areas of the transistor Tr are W1 and the current input value when both channel areas of the transistor Tr are W2. The probability of the leakage current of the transistor Tr increasing due to the increase in the average width of the channels is low, so that the overall leakage current is approximate to the leakage current when both channel areas of the transistor Tr have a smaller channel width. Moreover, the aforementioned characteristics may still be retained after the two channel widths corresponding to the source and the drain are interchanged. Therefore, the ratio of the channel width corresponding to the source (for example, the first width W1) to the channel width corresponding to the drain (for example, the second width W2) may be designed to be between 0.2 and 5 and not equal to 1 (that is, W1/W2=0.2~5, and W1/W2≠1). More specifically, when the first width W1 is designed to be greater than the second width W2, the ratio of the first width W1 to the second width W2 is greater than 1 and smaller than or equal to 5 (1<W1/W2≤5); when the second width W2 is designed to be greater than the first width W1, the ratio of the first width W1 to the second width W2 is greater than or equal to 0.2 and smaller than 1(0.2≤W1/W2<1).

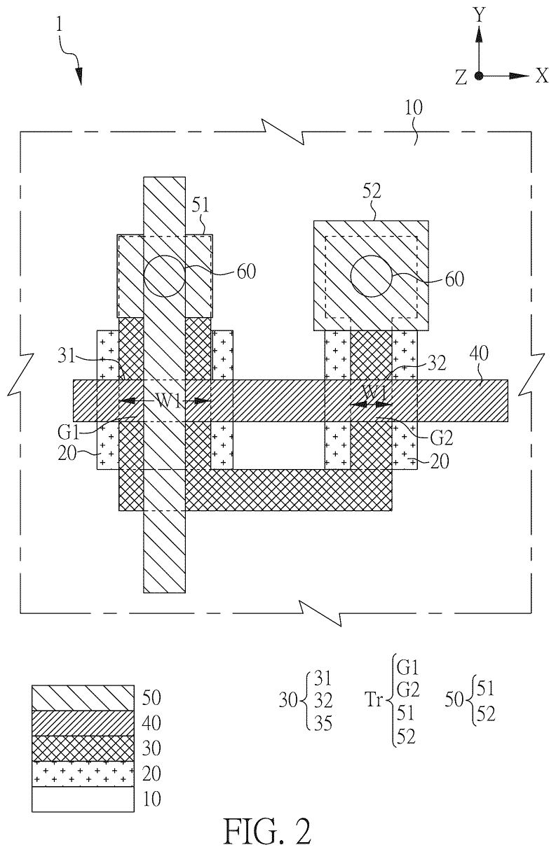

FIG. 2 is a schematic diagram illustrating the structural layout of an electronic device according to another embodiment of the present disclosure. Similar to the embodiment of FIG. 1A and FIG. 1B, the electronic device 1 of FIG. 2 may include a substrate 10, a metal shielding layer 20, a semiconductor layer 30, a first metal layer 40 and a second metal layer 50, wherein a portion of the semiconductor layer 30 overlapping with the first metal layer 40 is defined as a first channel area 31, and another portion of the semiconductor layer 30 overlapping with the first metal layer 40 is defined as a second channel area 32. This embodiment is different from the embodiment of FIG. 1A and FIG. 1B in that the second width W2 of the second channel area 32 is greater than the first width W1 of the first channel area 31, as shown in FIG. 2. In addition, the other features of this embodiment and the effects achieved thereby are applicable to the description of the embodiment of FIG. 1A and FIG. 1B, and thus a detailed description is deemed unnecessary.

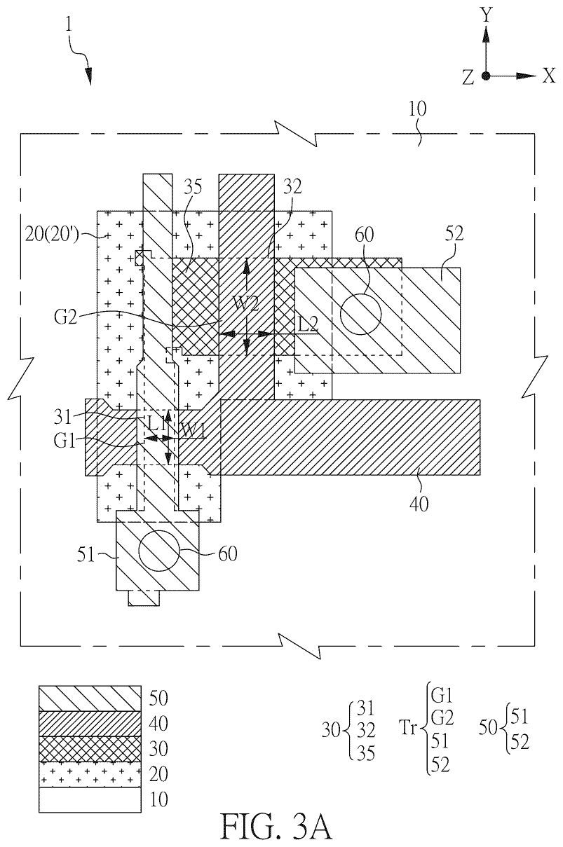

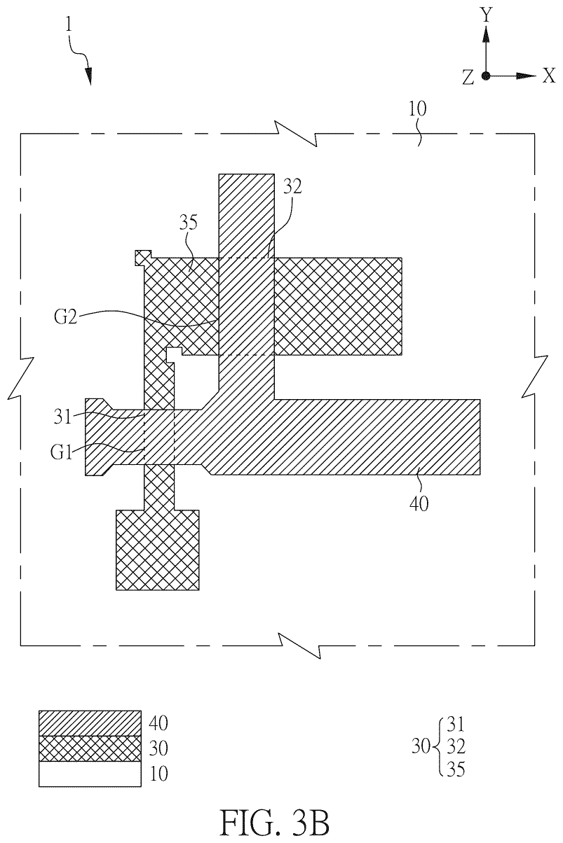

FIG. 3A is a schematic diagram illustrating the structural layout of an electronic device according to another embodiment of the present disclosure, and FIG. 3B is a schematic diagram illustrating the simplified structural layout of an electronic device according to another embodiment of the present disclosure. Similar to the embodiment of FIG. 1A and FIG. 1B, the electronic device 1 of FIG. 3A may include a substrate 10, a metal shielding layer 20, a semiconductor layer 30, a first metal layer 40, and a second metal layer 50, and FIG. 3B only shows the substrate 10, the semiconductor layer 30 and the first metal layer 40 to clearly illustrate the structural layout of the electronic device, wherein a portion of the semiconductor layer 30 overlapping with the first metal layer 40 is defined as a first channel area 31, and another portion of the semiconductor layer 30 overlapping with the first metal layer 40 is defined as a second channel area 32. Compared with the embodiment of FIG. 1A and FIG. 1B, this embodiment has a different circuit layout. In detail, in this embodiment, the relative position between the source and the drain, and the layout shapes of the semiconductor layer 30 and the first metal layer 40 are different from the embodiment of FIG. 1A and FIG. 1B. Therefore, the widths W1 and W2 of the two channel areas 31 and 32 of this embodiment are measured in different directions; that is, the first width W1 of the first channel area 31 is measured in the X direction, and the second width W2 of the second channel area 32 is measured in the Y direction. Furthermore, based on the fact that the layout positions of the source and the drain in FIG. 3A and FIG. 3B are relatively close, the metal shielding layer 20 may have only one shielding pattern 20′ to overlap the first channel area 31 and the second channel area 32, as shown in FIG. 3A and FIG. 3B. In addition, other features of this embodiment and the effects achieved thereby are applicable to the description of the embodiment of FIG. 1A and FIG. 1B, and therefore a detailed description is deemed unnecessary.

In view of the foregoing, it can be seen that, in the present disclosure, by adopting a design with different channel widths in a dual-gate transistor, a good current input value and a low leakage current value can be achieved, so as to effectively alleviate the problem of display flicker caused by leakage current that affects the screen performance, without sacrificing charging capacity.

In one embodiment, the present disclosure may at least determine whether the product in contest falls within the scope of protection of the present disclosure by the presence or absence of components, component configuration and/or operating mode, or may determine whether the product in contest falls within the scope of protection of the present disclosure by the circuit layout, but it is not limited thereto.

The features of the various embodiments of the present disclosure may be mixed and matched as needed as long as they do not violate the spirit of the disclosure or conflict with each other.

The aforementioned specific embodiments should be construed as merely illustrative, and not limiting the rest of the present disclosure in any way.

1. An electronic device, comprising:
a substrate;
a first metal layer disposed on the substrate;
a semiconductor layer disposed on the substrate and including a first channel area, a connection area, and a second channel area, wherein the first channel area and the second channel area overlap with the first metal layer, and the connection area connects the first channel area and the second channel area; and
a second metal layer disposed on the semiconductor layer and including a first pattern and a second pattern, wherein the first pattern is electrically connected to the first channel area, and the second pattern is electrically connected to the second channel area,
wherein the first channel area has a first width, the second channel area has a second width, and the first width is different from the second width.

2. The electronic device as claimed in claim 1, wherein the electronic device has at least one transistor, the first metal layer includes a first gate area and a second gate area of the at least one transistor, the first gate area overlaps with the first channel area, the second gate area overlaps with the second channel area, the first pattern is a source of the at least one transistor, and the second pattern is a drain of the at least one transistor.

3. The electronic device as claimed in claim 1, wherein a ratio of the first width to the second width is between 0.2 and 5, and is not equal to 1.

4. The electronic device as claimed in claim 3, wherein the first width is greater than the second width.

5. The electronic device as claimed in claim 3, wherein the second width is greater than the first width.

6. The electronic device as claimed in claim 1, wherein the first channel area has a first length, the second channel area has a second length, and the first length is equal to the second length.

7. The electronic device as claimed in claim 1, further comprising a metal shielding layer disposed between the substrate and the semiconductor layer, the metal shielding layer at least overlapping with the first channel area and the second channel area.

8. The electronic device as claimed in claim 7, wherein the metal shielding layer has two shielding patterns that overlap with the first channel area and the second channel area, respectively.

9. The electronic device as claimed in claim 1, wherein the first width and the second width are measured in same direction.

10. The electronic device as claimed in claim 1, wherein the first width and the second width are measured in different directions.

11. The electronic device as claimed in claim 1, wherein the first channel area is a portion of the semiconductor layer that overlaps with the first metal layer, the second channel area is another portion of the semiconductor layer that overlaps with the first metal layer, and the connection area is a portion of the semiconductor layer that connects the first channel area and the second channel area.

12. The electronic device as claimed in claim 2, wherein the first gate area is a portion of the semiconductor layer that overlaps with the first metal layer, and the second gate area is another portion of the semiconductor layer that overlaps with the first metal layer.

13. The electronic device as claimed in claim 2, wherein the source and the drain are each electrically connected to the semiconductor layer through a contact via between the second metal layer and the semiconductor layer.

14. The electronic device as claimed in claim 2, wherein the first width and the second width are each between 1.5 μm and 7.5 μm.

15. The electronic device as claimed in claim 7, wherein the metal shielding layer has a shielding pattern that overlaps with the first channel area and the second channel area.

16. The electronic device as claimed in claim 1, wherein the metal shielding layer, the semiconductor layer, the first metal layer, and the second metal layer are sequentially disposed on the substrate.

17. The electronic device as claimed in claim 1, wherein the semiconductor layer is arranged in a U-shape, and the first metal layer is arranged in a long rectangular shape.

18. The electronic device as claimed in claim 1, wherein the connection area 35 is U-shaped.

19. The electronic device as claimed in claim 1, wherein the first channel area has a first length, the second channel area has a second length, and the first length is not equal to the second length.

20. The electronic device as claimed in claim 17, wherein the first pattern and the second pattern overlap with the semiconductor layer and are respectively located at two ends of the U-shape of the semiconductor layer.
